(19) United States
(12) Patent Application Publication
(10) Pub. No.: US 2018/0005648 A1
(43) Pub. Date: Jan. 4, 2018

(54) METHOD OF MANUFACTURING PERPENDICULAR MAGNETIC RECORDING HEAD

(71) Applicant: TDK CORPORATION, Tokyo (JP)

(72) Inventors: Ken FUJII, Tokyo (JP); Hisayoshi WATANABE, Tokyo (JP); Masachika HASHINO, Tokyo (JP); Takamitsu SAKAMOTO, Tokyo (JP); Tetsuya HIRAKI, Tokyo (JP)

(73) Assignee: TDK CORPORATION, Tokyo (JP)

(21) Appl. No.: 15/197,342

(22) Filed: Jun. 29, 2016

(51) Int. Cl. G11B 5/127; C23C 16/455; C23C 16/04; C23C 16/40; G11B 5/39; G11B 5/11

(52) U.S. Cl. CPC G11B 5/1272; G11B 5/3912; G11B 5/112; C23C 16/042; C23C 16/403; C23C 16/45525

(57) ABSTRACT

This method of manufacturing a perpendicular magnetic recording head includes: forming a water-soluble resin film on a base; forming a first resist pattern having an opening on the water-soluble resin film; selectively dissolving the water-soluble resin film exposed at a bottom of the opening with a developer to expose a part of a surface of the base; forming a non-magnetic oxide film to cover the opening and the exposed part of the surface of the base; forming a second resist pattern to fill the opening covered with the non-magnetic oxide film and then removing the first resist pattern and the non-magnetic oxide film; forming a first side shield and a second side shield on the base to allow them to face each other with the second resist pattern therebetween; and forming a magnetic pole between the first and the second side shields after removal of the second resist pattern.

### BACKGROUND

The invention relates to a method of manufacturing a perpendicular magnetic recording head.

Surface recording density of magnetic recording media (referred to below as “recording media”), represented by hard disks, has recently increased. With this trend, magnetic recording heads having improved performance have been demanded. As a result, a longitudinal magnetic recording system in which an orientation of a signal magnetic field is set in an in-plane direction of a recording medium is being replaced by a perpendicular magnetic recording system in which an orientation of a signal magnetic field is set in a direction perpendicular to the in-plane. This perpendicular magnetic recording system is attracting attention as a recording system for magnetic recording heads. This is because the perpendicular magnetic recording system has the merits of increasing track recording density and resistance of recorded recording media to thermal fluctuation.

A magnetic recording head for the perpendicular magnetic recording system (referred to below as a “perpendicular magnetic recording head”) includes a thin film coil for generating a magnetic flux and a magnetic pole layer that guides the magnetic flux generated by the thin film coil to a recording medium. This magnetic pole layer includes an end part (magnetic pole) having a narrow width which generates a magnetic field for recording (recording magnetic field). Such perpendicular magnetic recording heads have been studied in various ways (for example, refer to U.S. Pat. No. 8,300,359, U.S. Pat. No. 8,400,732, and U.S. Pat. No. 7,898,773).

### SUMMARY

In the above circumstances, the recent trend toward higher recording density of recording media has boosted a demand for perpendicular magnetic recording heads to have more miniaturized structure. Thus, it is desirable to establish a method of manufacturing a perpendicular magnetic recording head, which allows for highly precise formation of perpendicular magnetic recording heads that have a miniaturized structure and are suitable for high density recording.

A method of manufacturing a perpendicular magnetic recording head according to an embodiment of the invention includes:

(1) forming a water-soluble resin film on a base;
(2) forming a first resist pattern having an opening on the water-soluble resin film;
(3) selectively dissolving the water-soluble resin film exposed at a bottom of the opening with a developer to expose a part of a surface of the base;
(4) forming a non-magnetic oxide film to cover the opening and the exposed part of the surface of the base;
(5) forming a second resist pattern to fill the opening covered with the non-magnetic oxide film and then removing the first resist pattern and the non-magnetic oxide film;
(6) forming a first side shield and a second side shield on the base to allow the first side shield and the second side shield to face each other with the second resist pattern therebetween; and
(7) forming a magnetic pole between the first side shield and the second side shield after removal of the second resist pattern.

In the method of manufacturing a perpendicular magnetic recording head according to an embodiment of the invention, the first resist pattern having the opening is formed on the water-soluble resin film, and this water-soluble resin film is dissolved. Therefore, even if the opening is small in size, it is possible to easily obtain the first resist pattern having a desired shape. Consequently, it is possible to improve dimensional precision of each of the first side shield and the second side shield that is formed afterward and the magnetic pole that is formed between the first side shield and the second side shield.

The method of manufacturing a perpendicular magnetic recording head according to an embodiment of the invention enables a perpendicular magnetic recording head including minute constituent elements each having a highly precise dimension to be manufactured, thus advantageously supporting high density recording.

### BRIEF DESCRIPTION OF DRAWINGS

FIG. 1 is a perspective view illustrating a configuration of a magnetic disk unit having thin film magnetic heads according to an embodiment of the invention.

FIG. 2 is a perspective view illustrating a configuration of a slider in the magnetic disk unit illustrated in FIG. 1.

FIG. 3 is a sectional diagram illustrating a structure of the thin film magnetic head illustrated in FIG. 2.

FIG. 4 is an enlarged, sectional diagram illustrating a cross section of the thin film magnetic head illustrated in FIG. 2, which is parallel to an air bearing surface.

FIG. 5A is a sectional diagram associated with FIG. 4, which illustrates one step in a method of manufacturing the thin film magnetic head illustrated in FIG. 2.

FIG. 5B is a sectional diagram illustrating one step that follows FIG. 5A.

FIG. 5C is a sectional diagram illustrating one step that follows FIG. 5B.

FIG. 5D is a sectional diagram illustrating one step that follows FIG. 5C.

FIG. 5E is a sectional diagram illustrating one step that follows FIG. 5D.

FIG. 5F is a sectional diagram illustrating one step that follows FIG. 5E.

FIG. 5G is a sectional diagram illustrating one step that follows FIG. 5F.

FIG. 5H is a sectional diagram illustrating one step that follows FIG. 5G.

FIG. 5J is a sectional diagram illustrating one step that follows FIG. 5H.

FIG. 5K is a sectional diagram illustrating one step that follows FIG. 5J.

FIG. 5L is a sectional diagram illustrating one step that follows FIG. 5K.

FIG. 5M is a sectional diagram illustrating one step that follows FIG. 5L.

FIG. 5N is a sectional diagram illustrating one step that follows FIG. 5M.

FIG. 5P is a sectional diagram illustrating one step that follows FIG. 5N.

FIG. 5Q is a sectional diagram illustrating one step that follows FIG. 5P.

FIG. 5R is a sectional diagram illustrating one step that follows FIG. 5Q.

FIG. 5S is a sectional diagram illustrating one step that follows FIG. 5R.

FIG. 5T is a sectional diagram illustrating one step that follows FIG. 5S.

FIG. 5U is a sectional diagram illustrating one step that follows FIG. 5T.

FIG. 5V is a sectional diagram illustrating one step that follows FIG. 5U.

FIG. 5W is a sectional diagram illustrating one step that follows FIG. 5V.

FIG. 5X is a sectional diagram illustrating one step that follows FIG. 5W.

FIG. 6A is a sectional diagram illustrating one step in a method of manufacturing a thin film magnetic head according to a reference example.

FIG. 6B is a sectional diagram illustrating one step that follows FIG. 6A.

### DETAILED DESCRIPTION

One embodiment of the invention will be described in detail below with reference to the drawings.

<Configuration of Magnetic Disk Unit>

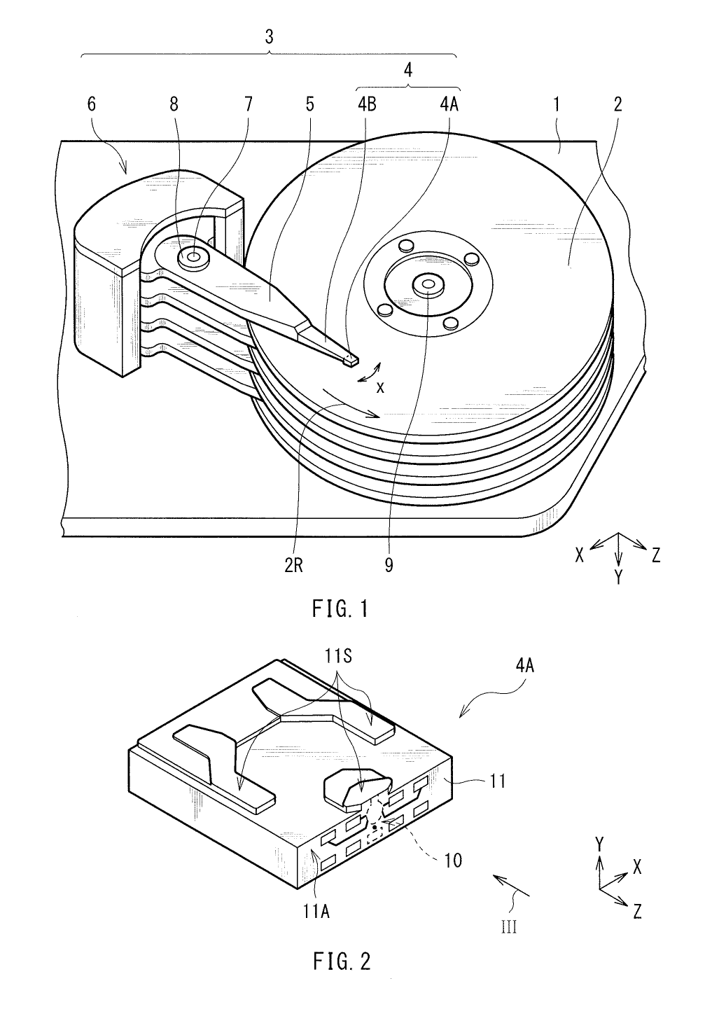

First, a configuration of a magnetic disk unit according to an embodiment of the invention will be described below with reference to FIG. 1 and FIG. 2. FIG. 1 is a perspective view illustrating an internal configuration of the magnetic disk unit according to the present embodiment. This magnetic disk unit adopts a load/unload operation system as a driving system and includes: for example, in a housing 1, magnetic disks 2 as magnetic recording media in which information is to be recorded; and a head arm assembly (HAA) 3 for recording information in the magnetic disks 2 and reproducing the information. The HAA 3 includes: head gimbals assemblies (HGAs) 4; arms 5 that support the bases of the HGAs 4; and a driver 6 as a power source to cause the arm 5 to pivot. Each HGA 4 includes: a magnetic head slider (simply abbreviated below as a “slider”) 4A having a side surface provided with a thin film magnetic head 10 (described later) according to the present embodiment; and a suspension 4B having an end provided with the slider 4A. The other end of the suspension 4B (the end opposite to the end provided with the slider 4A) is supported by the arm 5. The arms 5 are configured to be able to pivot around a fixed shaft 7 fixed to the housing 1 via a bearing 8. The driver 6 may be formed of a voice coil motor, for example. The magnetic disk unit has a plurality of (four in FIG. 1) magnetic disks 2. The sliders 4A are disposed in a manner corresponding to respective recording surfaces (front surfaces and back surfaces) of the magnetic disks 2. The sliders 4A are movable in a direction intersecting recording tracks (in an X-axis direction) in a plane parallel to the recording surfaces of the magnetic disks 2. The magnetic disks 2 rotate around a spindle motor 9 fixed to the housing 1 in a rotation direction 2R substantially orthogonal to the X-axis direction. The rotation of a magnetic disk 2 and the movement of a related slider 4A enable information to be recorded in the magnetic disk 2 or recorded information to be read out.

FIG. 2 illustrates a configuration of one of the sliders 4A illustrated in FIG. 1. This slider 4A has a block-shaped base 11, which may be made of ALTiC (Al₂O₃.TiC), for example. This base 11 may be formed into a substantially hexagonal shape, for example, and its surface is an air bearing surface (referred to below as ABS) 11S, which is disposed opposite and adjacent to a corresponding recording surface of the magnetic disk 2. When the magnetic disk unit is not driven, namely, when the spindle motor 9 stops and the magnetic disks 2 do not rotate, the sliders 4A are kept in the state (unloaded state) of being held at a site away from the upper sides of the magnetic disks 2 in order to prevent the ABSs 11S from making contact with the recording surfaces. When the magnetic disk unit is activated, the spindle motors 9 start to rotate the magnetic disks 2 at a high speed and the driver 6 causes the arms 5 to pivot on their central axis, or the fixed shaft 7. As a result, the sliders 4A move to the upper sides of the surfaces of the magnetic disks 2, entering a loaded state. The high-speed rotation of each magnetic disk 2 results in creation of airflow between the recording surface and the ABS 11S. The resultant lift force causes each slider 4A to be in a floating state so as to maintain a predetermined gap (magnetic spacing) in a direction orthogonal to the recording surface (in a Y-axis direction). In addition, the thin film magnetic head 10 is mounted on an element forming surface 11A, which is one side surface orthogonal to the ABS 11S.

<Detailed Configuration of Thin Film Magnetic Head 10>

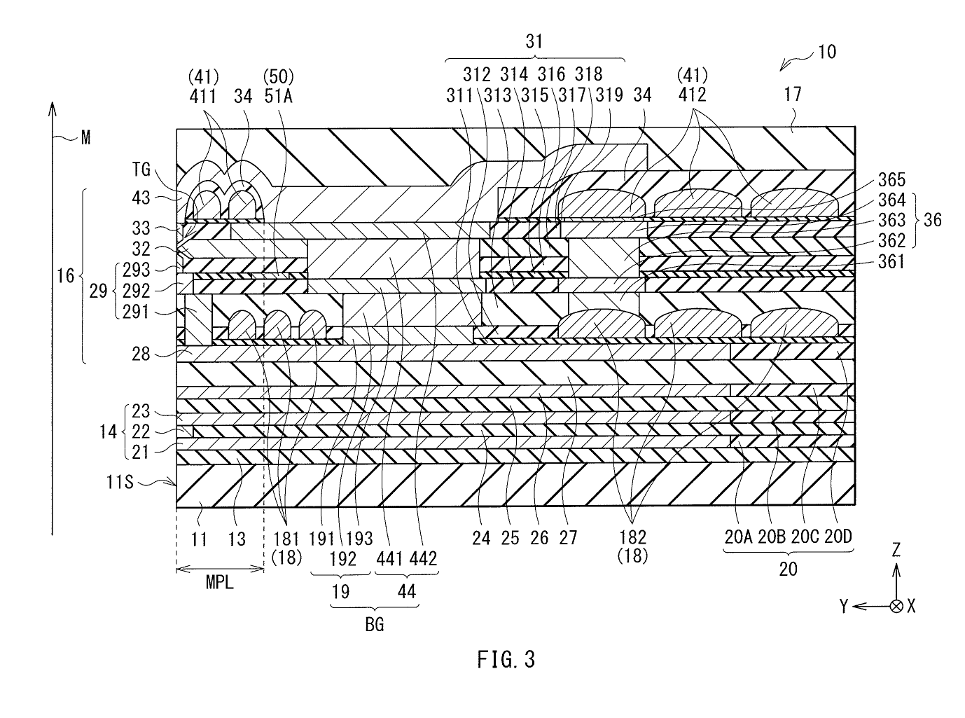

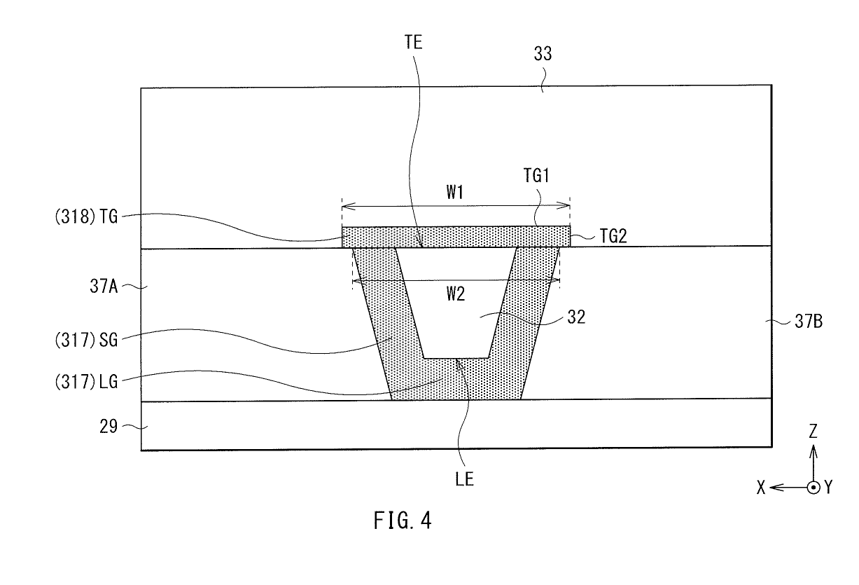

Next, the thin film magnetic head 10 will be described in more detail with reference to FIG. 3 and FIG. 4. FIG. 3 is a sectional diagram of the thin film magnetic head 10 in the middle in the X-axis direction. The upward arrow M illustrated in FIG. 3 denotes a moving direction of the magnetic disk 2 relative to the thin film magnetic head 10. FIG. 4 illustrates a structure of a cross section of the thin film magnetic head 10 parallel to the ABS 11S. It should be noted that the sectional structure illustrated in FIG. 4 is positioned quite adjacent to the ABSs 11S.

In the following description, the dimensions in the X-axis direction, the Y-axis direction, and the Z-axis direction are referred to as the “width”, “height”, and “thickness”, respectively. The side closer to the ABS 11S in the Y-axis direction is referred to as the “front”, whereas the farther side is referred to as the “rear”. Moreover, the front side and the back side in the direction of the arrow M are referred to as the “trailing side” and the “leading side”, respectively. The X-axis direction and the Z-axis direction are referred to as the “cross track direction” and the “down track direction”, respectively.

The thin film magnetic head 10 subjects the magnetic disk 2 to a magnetic processing. As one example, the thin film magnetic head 10 may be a composite head that allows for both a reproducing processing and a recording processing.

As illustrated in FIG. 3, for example, the thin film magnetic head 10 may include an insulating layer 13, a reproducing head section 14, a recording head section 16, and a protective layer 17 that are stacked on the base 11 in this order. One side surface common to these layers is the ABS 11S that the thin film magnetic head 10 has. Provided between the reproducing head section 14 and the recording head section 16 are an insulating layer 25, an intermediate shield layer 26, and an insulating layer 27, which are stacked on the reproducing head section 14 in this order.

Each of the insulating layer 13 and the protective layer 17 may be made of, for example, a non-magnetic insulating material, such as aluminum oxide. The aluminum oxide may be alumina (Al₂O₃), for example.

(Reproducing Head Section 14)

The reproducing head section 14 utilizes a magneto-resistive effect (MR) to perform the reproducing processing. This reproducing head section 14 may include, for example a lower shield layer 21, an MR element 22, and an upper shield layer 23, which are stacked on the insulating layer 13 in this order.

Each of the lower shield layer 21 and the upper shield layer 23 may be made of, for example, a soft magnetic metal material, such as a nickel-iron alloy (NiFe). The lower shield layer 21 and the upper shield layer 23 are disposed opposite each other with the MR element 22 therebetween in a stacking direction (in the Z-axis direction). Each of the lower shield layer 21 and the upper shield layer 23 has an end surface exposed from the ABS 11S and extends rearward from the ABS 11S. With this configuration, the lower shield layer 21 and the upper shield layer 23 fulfil the function of magnetically isolating the MR element 22 from its environment and protecting the MR element 22 from unwanted influence of a magnetic field.

One end surface of the MR element 22 is exposed from the ABS 11S, and the other end surface is in contact with an insulating layer 24 embedded in the space between the lower shield layer 21 and the upper shield layer 23. The insulating layer 24 may be made of an insulating material, such as aluminum oxide (Al₂O₃), aluminum nitride (AlN), silicon dioxide (SiO₂), or diamond-like carbon (DLC).

The MR element 22 functions as a sensor that reads out magnetic information recorded in the magnetic disk 2. The MR element 22 may be, for example a CPP (current perpendicular to plane)-GMR (giant magnetoresistive) element, through which sense current flows in a stacking direction. In this case, the lower shield layer 21 and the upper shield layer 23 function as electrodes to allow the sense current to be supplied to the MR element 22.

In the reproducing head section 14 configured above, a magnetization direction of a free layer (not illustrated) contained in the MR element 22 changes in accordance with a signal magnetic field from the magnetic disk 2. Thus, the magnetization direction of the free layer changes relative to a magnetization direction of a pinned layer (not illustrated) also contained in the MR element 22. When the sense current flows through the MR element 22, the relative change in the magnetization direction emerges as a variation in the electric resistance. Thus, by using this variation, a signal magnetic field is detected and magnetic information is read out.

As described above, the insulating layer 25, the intermediate shield layer 26, and the insulating layer 27 are stacked on the reproducing head section 14 in this order. Embedded in the insulating layer 27 may be a resistance sensor (not illustrated) with its part exposed from the ABS 11S. A lower yoke 28 forming a part of the recording head section 16 is provided on the insulating layer 27. The space behind the lower shield layer 21 is occupied by an insulating layer 20A. The space behind the upper shield layer 23 is occupied by an insulating layer 20B. The space behind the intermediate shield layer 26 is occupied by an insulating layer 20C. The space behind the lower yoke 28 is occupied by an insulating layer 20D. Herein, in some cases, the insulating layers 20A to 20D are collectively referred to as the insulating layer 20. The intermediate shield layer 26, which may be made of, for example a soft magnetic metal material, such as NiFe, functions to prevent a magnetic field generated in the recording head section 16 from reaching the MR element 22. Each of the insulating layers 25 and 27 may be made of a material similar to the insulating layer 24, for example.

(Recording Head Section 16)

The recording head section 16 is a so-called perpendicular magnetic recording head that performs the recording processing in a perpendicular magnetic recording system. The recording head section 16 may include: for example, the lower yoke 28; a lower coil 18 and a leading shield 29 that are embedded in the insulating layer 31; a magnetic pole 32; a trailing shield 33; an upper coil 41 embedded in the insulating layer 34; and an upper yoke 43, which are stacked on the insulating layer 27 in this order. The space between the lower coil 18 and the upper coil 41 behind the leading shield 29 is occupied by the insulating layer 31 (311 to 319). The magnetic pole 32 is apart from the trailing shield 33, and the insulating layer 318 fills a gap between them, forming a write gap WG.

The recording head section 16 further includes a back gap BG; the back gap BG includes: a lower back gap 19 connected to the lower yoke 28; and an upper back gap 44 connected to the upper yoke 43. The lower back gap 19 includes magnetic layers 191 to 193 stacked on the lower yoke 28 in this order. The upper back gap 44 includes a magnetic layer 441 and a magnetic layer 442 stacked, in this order, on the magnetic layer 193 of the lower back gap 19. Further, the upper surface of the magnetic layer 442 is in contact with the lower surface of the upper yoke 43.

In response to current supply, the upper coil 41 generates a magnetic flux for recording inside a magnetic path constituted primarily by the leading shield 29, the lower yoke 28, the lower back gap 19, the upper back gap 44, the upper yoke 43, and the magnetic pole 32. The lower coil 18 primarily generates a magnetic flux for suppressing a leakage in order to prevent the magnetic flux for recording generated in the upper coil 41 from accidentally reaching (leaking into) the reproducing head section 14. Current flows through the lower coil 18 in the direction opposite to that in which the current flows through the upper coil 41. Each of the lower coil 18 and the upper coil 41 may be made of, for example a highly-electroconductive material such as copper (Cu) and has a structure (a spiral structure) in which each of the lower coil 18 and the upper coil 41 is wound so as to surround the region occupied by the back gap BG (the lower back gap 19 and the upper back gap 44) in the stacked-layer plane (XY plane). The lower coil 18 is provided on the insulating layer 311 and is embedded in both the insulating layer 312 and the insulating layer 313. The upper coil 41 is provided on the insulating layer 319 and is embedded in the insulating layer 34. A part of a backward part 182 of the lower coil 18 is coupled to a part of a backward part 412 of the upper coil 41 via a pillar 36 that extends in a thickness direction so as to penetrate the insulating layer 31. The lower coil 18 is connected in series to the upper coil 41 via the pillar 36. The pillar 36 has a stacked structure in which electroconductive layers 361 to 365 are stacked in this order between the backward part 182 of the lower coil 18 and the backward part 412 of the upper coil 41.

Forward parts 181 of the lower coil 18, namely, the part of the lower coil 18 positioned between the lower back gap 19 and the ABS 11S may preferably be smaller in size in the Y-axis direction than backward parts 182 of the lower coil 18 that are positioned behind the lower back gap 19 (FIG. 3). Likewise, forward parts 411 of the upper coil 41 that are positioned between the upper back gap 44 and the ABS 11S may be preferably smaller in size in the Y-axis direction than backward parts 412 of the upper coil 41 that are positioned behind the upper back gap 44 (FIG. 3). This is because downsizing the forward parts 181 and the forward parts 411 in the Y-axis direction in this manner advantageously shortens a magnetic path length MPL (see FIG. 3).

Each of the lower yoke 28, the leading shield 29, the lower back gap 19, the upper yoke 43, the upper back gap 44, and the pillar 36 may be made of, for example a soft magnetic metal material, such as NiFe. The lower yoke 28 is magnetically coupled to the upper yoke 43 via the back gap BG. The leading shield 29 is coupled to a forward part of the upper surface of the lower yoke 28 and disposed so as to be partly exposed from the ABS 11S. The leading shield 29 may have a structure, for example in which a lower layer part 291, an intermediate part 292, and an upper layer part 293 are stacked in this order along the ABS 11S. In the example of FIG. 4, the lower layer part 291 is formed at a location slightly recessed from the ABS 11S, and the intermediate part 292 and the upper layer part 293 are formed so as to be exposed from the ABS 11S. The insulating layers 311 to 316 are stacked in this order behind the leading shield 29 so as to cover the lower yoke 28 and so as to cause the lower coil 18 to be embedded therein.

The leading shield 29 functions as a return path on the leading side and disperses some recording magnetic field emitted from the magnetic pole 32 toward the leading side, thereby attempting to reduce a wide adjacent track erase (WATE) effective magnetic field. The WATE effective magnetic field refers to an effective magnetic field that affects adjacent tracks over a wide range (for example, two to ten adjacent lanes of tracks with respect to a track to be written).

The magnetic pole 32 includes an end surface exposed from the ABS 11S and extends backward from the ABS 11S. The magnetic pole 32 may be made of, for example a magnetic material with a high saturation flux density, such as an iron-based alloy. Examples of this iron-based alloy may include an iron-cobalt alloy (FeCo) and an iron-cobalt-nickel alloy (FeCoNi). This magnetic pole 32 accommodates the magnetic flux generated in the lower coil 18 and the upper coil 41 and releases the magnetic flux from the end surface exposed from the ABS 11S, thereby generating a recording magnetic field.

In the recording head section 16 configured above, current (write current) flowing through the upper coil 41 causes a magnetic flux to be generated inside the magnetic path primarily constituted by the leading shield 29, the lower yoke 28, the lower back gap 19, the upper back gap 44, the upper yoke 43, and the magnetic pole 32. As a result, the recording magnetic field (signal magnetic field) is generated near the end surface of the magnetic pole 32 which is exposed from the ABS 11S. Then, the recording magnetic field reaches a predetermined region on the recording surface of the magnetic disk 2.

(Detailed Configuration of Recording Head Section 16)

A detailed configuration of the recording head section 16 will be described with reference to FIG. 4. In FIG. 4, shaded patterns are drawn in only constituent elements each made of an insulating material, and the other constituent elements are illustrated with a white background, for the purpose of better visibility.

As illustrated in FIG. 4, the recording head section 16 includes: the magnetic pole 32 that is formed on the leading shield 29 with a leading gap LG (a part of the insulating layer 317) therebetween; and a pair of side shields 37A and 37B that is disposed opposite each other in the cross track direction with the magnetic pole 32 and a pair of side gaps SG (other parts of the insulating layer 317) therebetween. The recording head section 16 further includes a trailing gap TG (a part of the insulating layer 318) formed so as to cover the magnetic pole 32 and the pair of side gaps SG. The trailing gap TG has a width W1 in the cross track direction.

The recording head section 16 further includes a trailing shield 33 formed so as to cover the trailing gap TG and the pair of side shields 37A and 37B. The trailing shield 33 is formed so as to cover both a surface TG1 and end surfaces TG2 of the trailing gap TG. In this case, a part of the trailing shield 33 (for example, a part covering the trailing gap TG) may be made of a material having a higher saturated magnetic flux density (high saturated magnetic flux density material) than the remaining part of the trailing shield 33 and the pair of side shields 37A and 37B. This is because, by using a high saturated magnetic flux density material for the part of the trailing shield 33, it is possible to expect that a return field increases toward the trailing side, improving the recording magnetic field and a gradient of the recording magnetic field. Specific examples of the above material having a saturated magnetic flux density may include materials containing FeCo (iron-cobalt alloy), FePd (iron-palladium alloy), FeCoPd (iron-cobalt-palladium alloy), and FeN (iron nitride).

As illustrated in FIG. 4, the magnetic pole 32 is trapezoidal in cross section, with a trailing edge TE having a larger width than a leading edge LE. A width W2, which is the total of the width of the trailing edge TE of the magnetic pole 32 and widths of the pair of side gaps SG in the cross track direction, is preferably set to be equal to or smaller than the width W1 of the trailing gap TG.

<Method of Manufacturing Thin Film Magnetic Head>

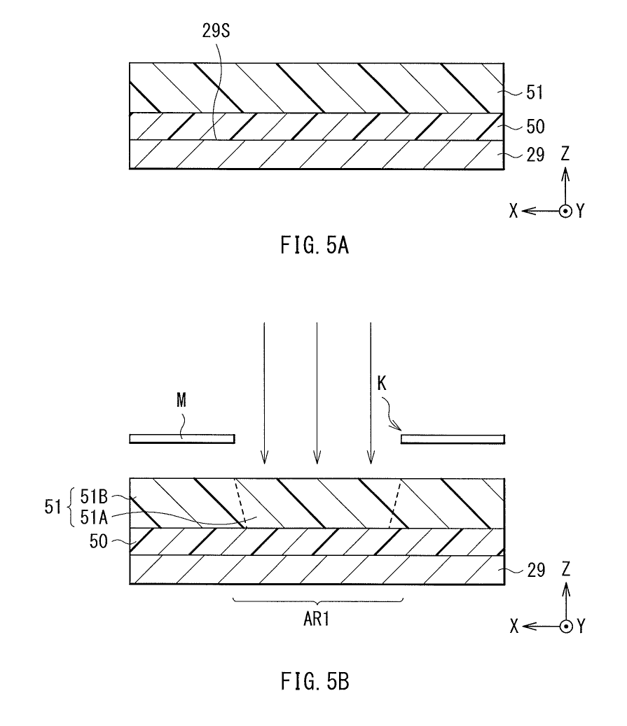

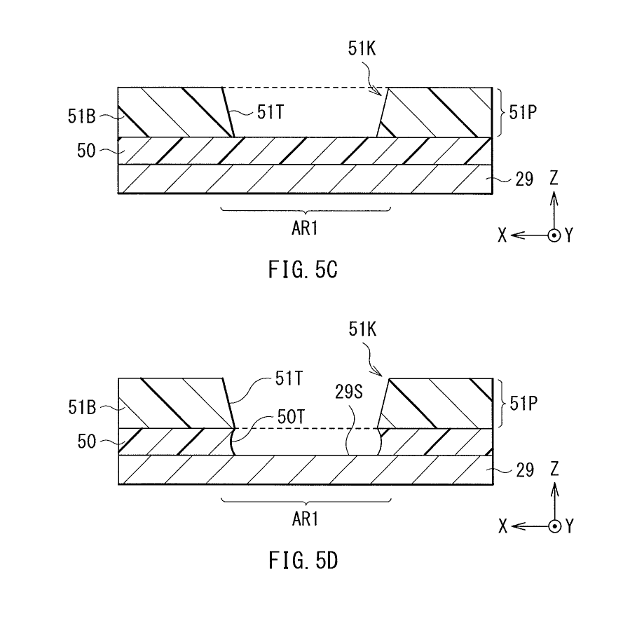

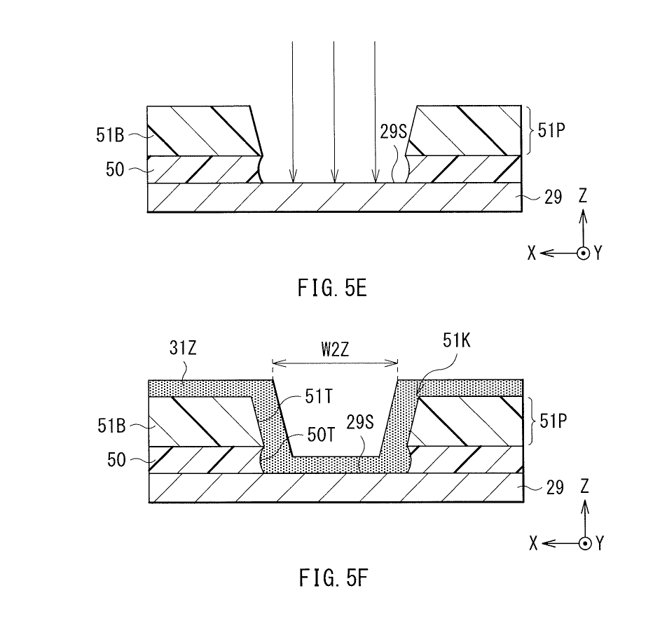

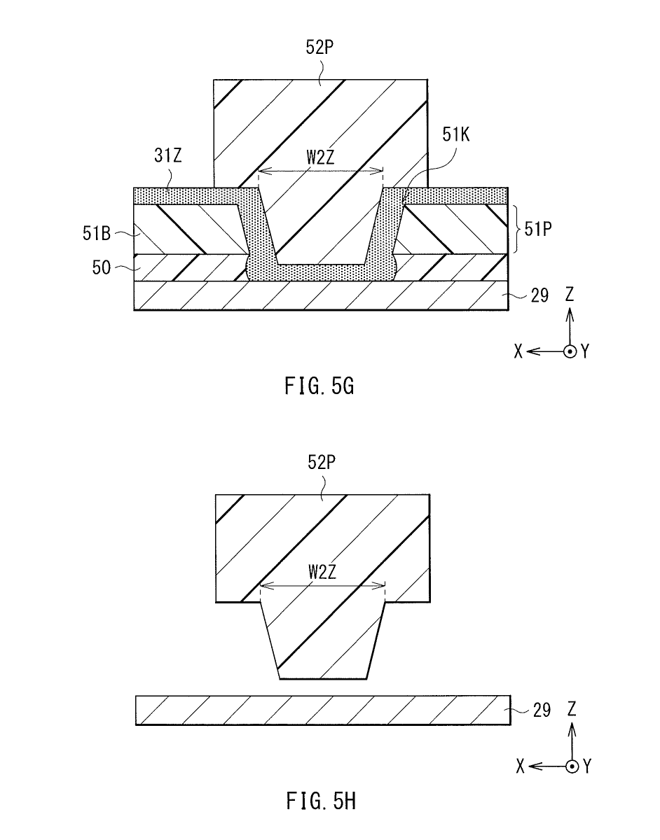

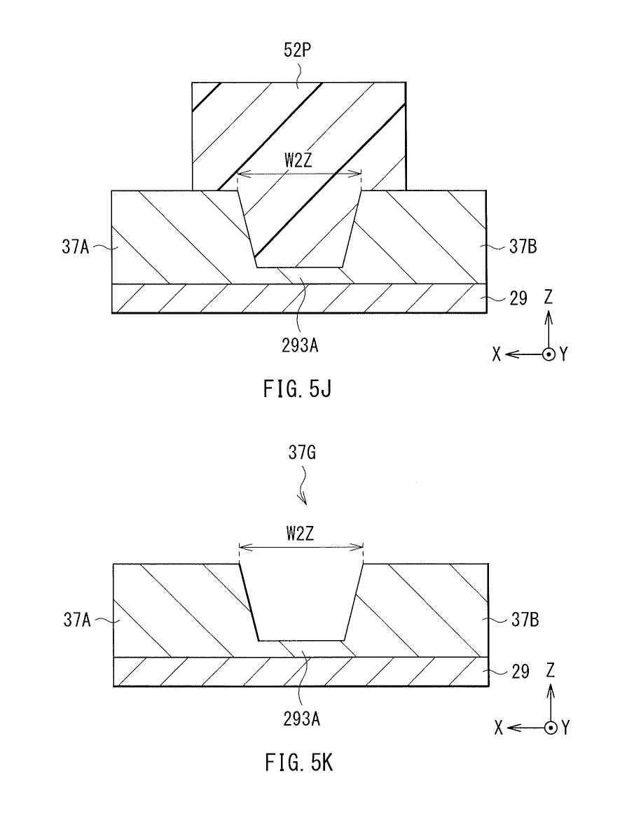

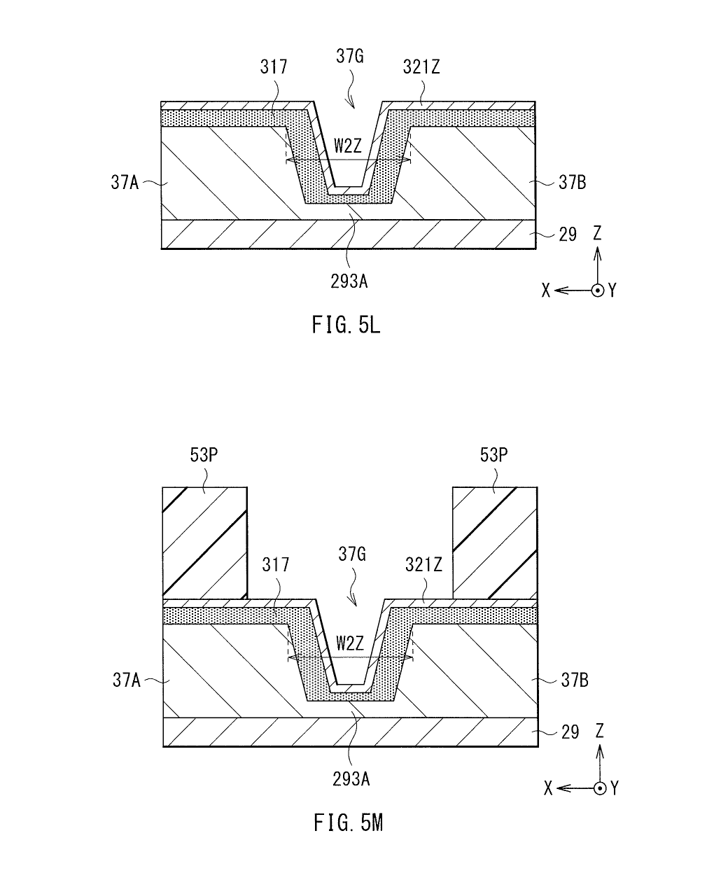

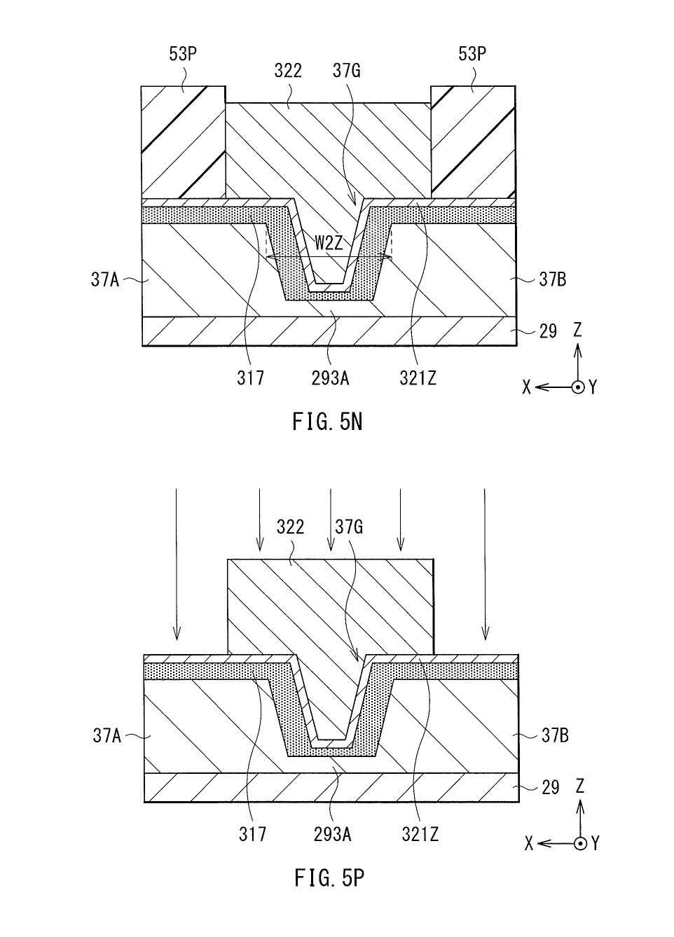

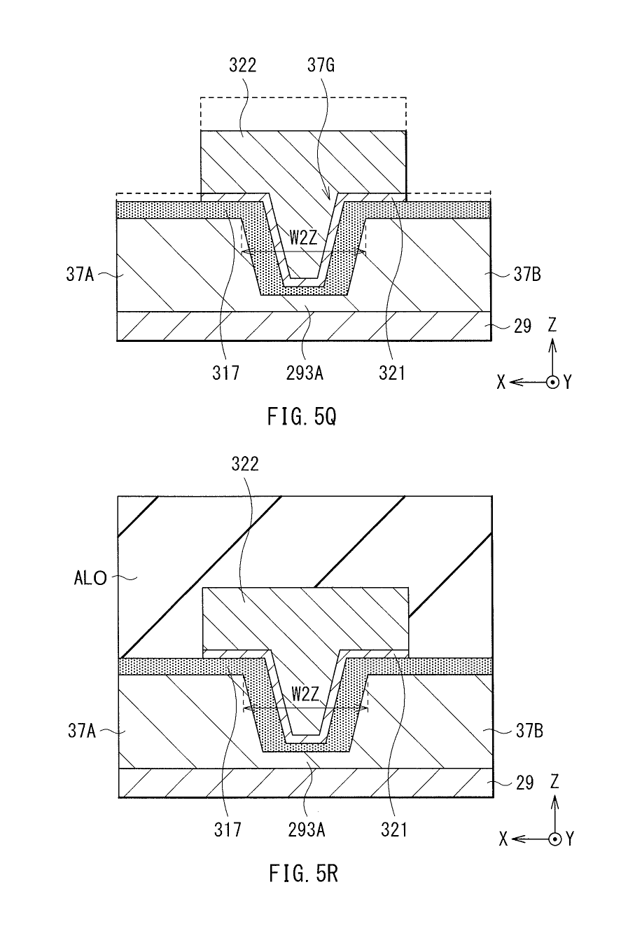

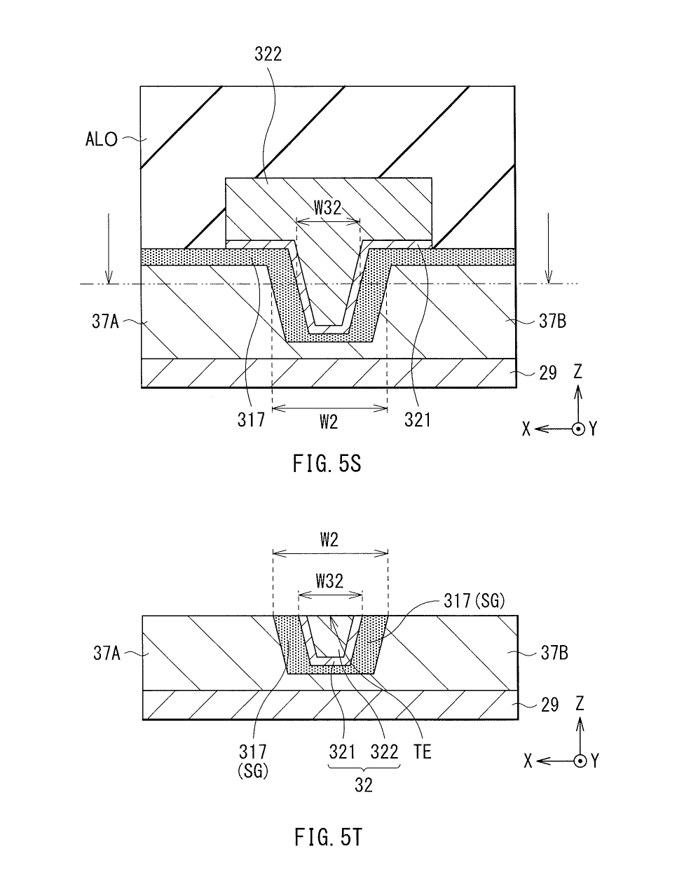

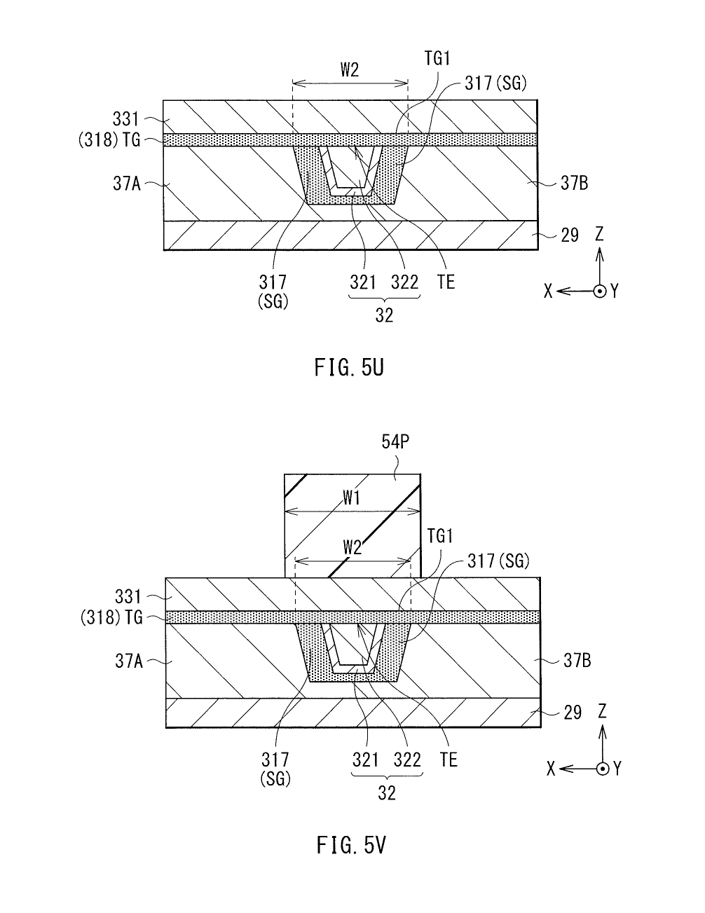

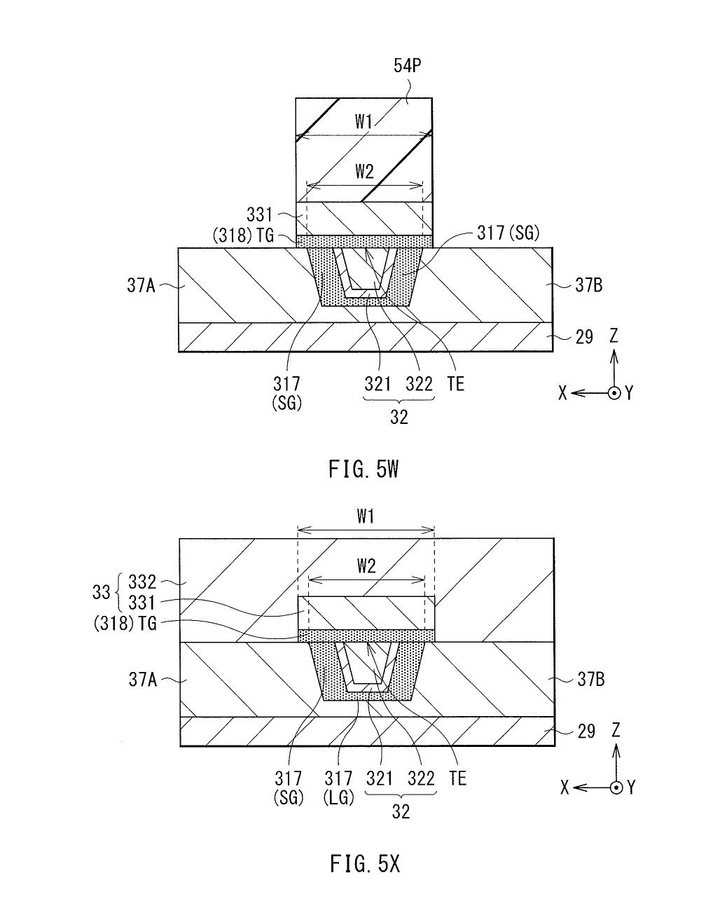

Next, a method of manufacturing the thin film magnetic head will be described. FIG. 5A to FIG. 5X illustrate respective steps in a method of manufacturing a main part of the thin film magnetic head 10, and are sectional diagrams illustrating a cross section that will turn out to be the ABS 11. Hereinafter, first, an outline of overall manufacturing processing will be described with reference to FIG. 3 and FIG. 4. Then, manufacturing processing for the main part will be described in detail with reference to FIG. 5A to FIG. 5X.

[Outline]

The thin film magnetic head 10 is manufactured primarily by sequentially forming and stacking a series of constituent elements through an existing thin film process. Examples of this existing thin film process may include: a film forming technique, such as an electrolytic plating method or a sputtering method; a patterning technique, such as a photolithography method; an etching technique, such as a dry etching method or a wet etching method; and a polishing technique, such as a chemical mechanical polishing (CMP) method.

When the thin film magnetic head 10 is manufactured, as illustrated in FIG. 3, first the insulating layer 13 is formed on the element forming surface 11A of the base 11. Subsequently, the reproducing head section 14, the insulating layer 25, the intermediate shield layer 26, the insulating layer 27, and the recording head section 16 are sequentially formed on the insulating layer 13. Then, the protective layer 17 is formed on the recording head section 16, after which a planarizing processing using the CMP method, for example, is applied to the protective layer 17. Finally, a side surface of the stacked structure constituted by the base 11 to the protective layer 17 is subjected to a predetermined process, such as a mechanical polishing and pattern etching processing, thereby fabricating the ABS 11S. Through this process, the thin film magnetic head 10 including the reproducing head section 14 and the recording head section 16 is completed.

[Method of Manufacturing Main Part]

The main part of the thin film magnetic head 10 may be fabricated as follows, for example. First, as illustrated in FIG. 5A, a water-soluble resin is applied to an upper surface (surface) 29S of the leading shield 29 to form a water-soluble resin film 50. Examples of the water-soluble resin used herein may include polymethylglutarimide (PMGI), polyacrylic acid, polyvinyl acetal, polyvinyl pyrrolidone, polyvinyl alcohol, polyethyleneimine, polyethylene oxide, styrene-maleic acid copolymer, a polyvinylamine resin, polyallylamine, an oxazoline group-containing water-soluble resin, a water-soluble melamine resin, a water-soluble urea resin, an alkyd resin, and a sulfonamide resin. After formation of the water-soluble resin film 50, a first resist film 51 is formed so as to cover the water-soluble resin film 50. The first resist film 51 may be made of a positive resist, for example.

Then, as illustrated in FIG. 5B, a mask M having an opening K is used to perform a first exposure processing, in which a part of the first resist film 51 is selectively exposed. In this case, a section 51A of the first resist film 51 occupying a region AR1 under which the opening K is placed is exposed. As a result, a latent image is formed in the section 51A of the first resist film 51.

Furthermore, the section 51A subjected to the first exposure processing is selectively dissolved in a developer. As a result, a section 51B of the first resist film 51 other than the section 51A is allowed to remain, and a first resist pattern 51P including an opening 51K is formed (FIG. 5C). An end surface 51T in the opening 51K slopes with respect to the stacked surface (XT plane).

The removal of the section 51A brings the water-soluble resin film 50 into contact with the developer. Thus, the part of the water-soluble resin film 50 which occupies the region AR1 is also dissolved in the developer (FIG. 5D). In this case, a developing time and the like may be preferably adjusted such that an end surface 50T is formed at the same location as the end surface 51T of the first resist pattern 51P or at a location slightly recessed from the end surface 51T. Dissolving the water-soluble resin film 50 results in the emergence of the upper surface 29S of the leading shield 29 in the region AR1.

Thereafter, as illustrated in FIG. 5E, the surface 29S of the leading shield 29 is preferably subjected to ashing. This ashing enables the water-soluble resin film 50 remaining on the surface 29S to be removed enough.

Thereafter, as illustrated in FIG. 5F, an insulating layer 31Z is formed so as to cover the opening 51K and the exposed surface 29S with no gap therebetween. In other words, the insulating layer 31Z seamlessly, or continuously, covers the end surface 51T, the end surface 50T, and the surface 29S. The insulating layer 31Z may be formed by a sputtering method or an atomic layer deposition (ALD) method using aluminum oxide (Al₂O₃) or magnesium oxide, for example. In this case, a distance W2Z between the parts of the insulating layer 31Z which cover the opposing pair of end surfaces 51T may be preferably set to be greater than the width W2. In the present embodiment, a good contact is ensured between the insulating layer 31Z and the surface 29S, because the remaining water-soluble resin film 50 has been removed enough from the surface 29S through the ashing processing illustrated in FIG. 5E.

Thereafter, as illustrated in FIG. 5G, a second resist pattern 52P is formed so as to fill the opening 51K covered with the insulating layer 31Z. In this case, the second resist pattern 52P may be made of a negative resist. The presence of the insulating layer 31Z prevents mixing of the first resist pattern 51P and the second resist pattern 52P.

After formation of the second resist pattern 52P, a second exposure processing in which the entire surfaces of the first resist pattern 51P and the second resist pattern 52P are exposed is performed. Then, both of the first resist pattern 51P and the second resist pattern 52P are immersed in a developer. As a result, as illustrated in FIG. 5H, the first resist pattern 51P and the water-soluble resin film 50 are dissolved in the developer. However, the second resist pattern 52P is not dissolved in the developer and is allowed to remain accordingly. The insulating layer 31Z is removed due to the dissolution of the first resist pattern 51P and the water-soluble resin film 50. However, the part of the insulating layer 31Z, other than the region adjacent to the ABS 11S, which is formed between the second resist pattern 52P and the leading shield 29 is allowed to remain. This is because the contact is reliably ensured between the insulating layer 31Z and the surface 29S in the present embodiment, as described above.

Then, as illustrated in FIG. 5J, a side shield 37A and a side shield 37B are formed on the upper surface 29S of the leading shield 29 with a plating method, for example, so as to face each other with the remaining second resist pattern 52P therebetween. In this case, a plating film 293A is also formed in the part between the remaining second resist pattern 52P and the leading shield 29 so as to join the side shield 37A to the side shield 37B.

Subsequently, the second resist pattern 52P is removed, and a recess 37G emerges accordingly, as illustrated in FIG. 5K. Thereafter, as illustrated in FIG. 5L, an insulating layer 317 and a metal magnetic film 321Z are sequentially formed and stacked with a sputtering method, for example, so as to cover the upper surfaces of the side shield 37A and the side shield 37B and the recess 37G, which is a gap between the side shield 37A and the side shield 37B.

Moreover, as illustrated in FIG. 5M, a third resist pattern 53P is selectively formed in the region on the metal magnetic film 321Z, other than the gap 37G and its adjacent area. Thereafter, as illustrated in FIG. 5N, a magnetic layer 322 is formed on the exposed region of the metal magnetic film 321Z which is not covered with the third resist pattern 53P, with a plating processing using the metal magnetic film 321Z as an electrode.

Furthermore, the third resist pattern 53P is removed, and then milling is performed, as illustrated in FIG. 5P. As a result, as illustrated in FIG. 5Q, the metal magnetic film 321Z is removed from the exposed region that is not covered with the magnetic layer 322 (the region covered with the third resist pattern 53P in FIG. 5N). At the same time, the upper layer part of the magnetic layer 322 is also removed.

Thereafter, as illustrated in FIG. 5R, an aluminum oxide (Al₂O₃) layer ALO is formed so as to cover the insulating layer 317 and the magnetic layer 322. Then, as illustrated in FIG. 5S, etching is performed so as to reach the predetermined site indicated by the alternate long and two short dashes line. More specifically, a polishing processing is performed throughout, and a milling processing is performed to form a slope in the magnetic pole 32 on the trailing side. Consequently, as illustrated in FIG. 5T, the pair of side shields 37A and 37B, the magnetic pole 32, which is constituted by the magnetic layer 321 and the magnetic layer 322 formed between the side shields 37A and 37B, and the insulating layer 317 (side gap SG and leading gap LG), which fills the gap between the magnetic pole 32 and the pair of side shields 37A and 37B, emerge on the leading shield 29. In this case, the polishing processing and the milling processing are performed such that the magnetic pole 32 has a width W32 at the trailing edge TE and the total of the width W32 of the magnetic pole 32 and the width of the insulating layer 317 (the pair of side gaps SG) is equal to the width W2.

Then, as illustrated in FIG. 5U, the insulating layer 318 (that will turn out to be the trailing gap TG) is formed so as to cover the entire surfaces of the magnetic pole 32, the pair of side shields 37A and 37B, and the pair of side gaps SG (insulating layers 317). In addition, a magnetic layer 331 made of iron-cobalt alloy (FeCo) is formed so as to cover the surface TG1 of the insulating layer 318.

Then, as illustrated in FIG. 5V, a fourth resist pattern 54P is formed so as to cover the region over the magnetic layer 331 which corresponds to the magnetic pole 32 and the pair of side gaps SG. In this case, the fourth resist pattern 54P is formed to have the width W1

Then, as illustrated in FIG. 5W, the exposed regions of the magnetic layer 331 and the insulating layer 318 which are not covered with the fourth resist pattern 54P are selectively etched using the fourth resist pattern 54P as a mask. In this case, milling or reactive ion etching (RIE), for example, may be performed. As a result, a part of the insulating layer 318 turns out to be the trailing gap TG having a planar shape which conforms to the fourth resist pattern 54P. In addition, the pair of side shields 37A and 37B is exposed.

Thereafter, by removing the fourth resist pattern 54P, the magnetic layer 331 becomes exposed. Then, as illustrated in FIG. 5X, a magnetic layer 332 is formed so as to cover the entire surfaces of the trailing gap TG and the pair of side shields 37A and 37B. In this case, the magnetic layer 332 is formed so as to cover the surface TG1 and the end surface TG2 of the trailing gap TG. Through the above processing, the trailing shield 33 is formed.

In the above way, the main part of the thin film magnetic head 10 is completed.

[Operation and Effect of Magnetic Disk Unit]

Next, a description will be given of an operation and an effect of the magnetic disk unit equipped with the thin film magnetic head 10 configured above.

When writing (recording) and reading out (reproducing) magnetic information, the magnetic disk unit uses the spindle motor 9 to rotate the magnetic disk 2 at a high speed in the direction of the arrow 2R (FIG. 1), thereby causing the slider 4A to float over the recording surface of the magnetic disk 2. In this case, the ABS 11S of the slider 4A (thin film magnetic head 10) faces the recording surface of the magnetic disk 2 with a predetermined spacing therebetween.

To record the magnetic information at a high density, a width of the magnetic pole 32 in the cross track direction is preferably narrowed.

In the present embodiment, in this respect, when the magnetic pole 32 is formed, the water-soluble resin film 50 is provided as the lower layer for the first resist pattern 51P. Therefore, the opening 51K of the first resist pattern 51P is formed with higher dimensional precision.

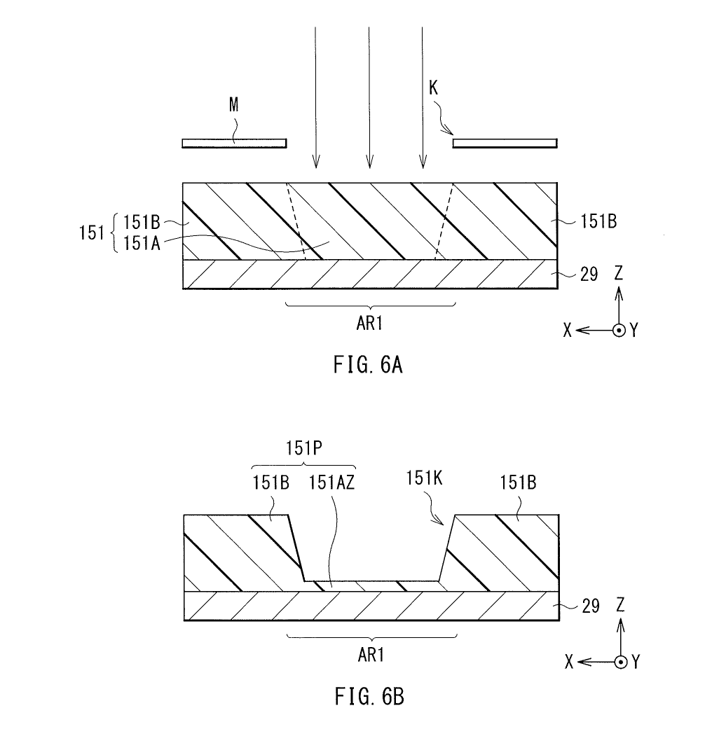

On the other hand, when a first resist film 151 is directly formed on a base without the provision of the water-soluble resin film 50 (FIG. 6A) and then a first resist pattern 151P is formed (FIG. 6B), for example, as a reference example illustrated in FIG. 6A and FIG. 6B, the following problem may arise. More specifically, when a narrow opening 151K is formed by using the mask M to selectively expose a part 151A of the first resist film 151 and then by dissolving the exposed part 151A in a developer, dimensional precision of the opening 151K is prone to be lowered. This is because the boundary between the exposed part (part 151A) and the unexposed parts (parts 151B) may be indefinite in the first resist film 151. Therefore, for example, the pair of parts 151B to be separated from each other may be joined together by a remaining part 151AZ in the deepest part of the first resist pattern 151P (in the vicinity of the surface 29S).

In contrast, according to the present embodiment, a bilayer structure in which the water-soluble resin film 50 and the first resist film 51 are stacked is formed on the base, after which the first resist film 51 is selectively exposed and washed. As a result, the section 51A to be dissolved and removed is reliably dissolved and removed. As a result, the opening 50K is formed with higher dimensional precision; thus the magnetic pole 32 is formed into a narrower and more precise dimensional shape. Therefore, according to the method of manufacturing the thin film magnetic head 10 in the present embodiment, it is possible to achieve the thin film magnetic head 10 that has a miniaturized structure and is suitable for even higher density recording, and to achieve the magnetic disk unit and the like equipped with the thin film magnetic head 10.

According to the present embodiment, the water-soluble resin film 50 is dissolved so that the surface 29S of the leading shield 29 is partly exposed (FIG. 5D). Then, before formation of the insulating layer 31Z, the exposed surface 29S is subjected to ashing (FIG. 5E). In this case, even if the water-soluble resin film 50 remains on the surface 29S, it is possible to remove the water-soluble resin film 50 enough. It is thus possible to sufficiently enhance the contact between the insulating layer 31Z that is formed afterward and the surface 29S, which is the underlayer for the insulating layer 31Z (FIG. 5F). In this case, even after the first resist pattern 51P and the water-soluble resin film 50 is dissolved and removed by a developer, the part of the insulating layer 31Z between the second resist pattern 52P and the leading shield 29, other than the part adjacent to the ABS 11S, is not etched and allowed to remain. Consequently, it is possible to suppress a plating film from extending (impregnating) to an unwanted region during a plating processing to be performed afterward, thereby forming the pair of side shields 37A and 37B having a highly precise dimension and shape through a plating processing.

For the above reasons, the present embodiment is advantageous to support high-density recording.

<Modification>

Although the invention has been described using the embodiment, the invention is not limited to the foregoing embodiment and may be modified in various manners. As one example, the perpendicular magnetic recording head of the invention is applied to a composite head; however, its application is not necessarily limited thereto. Alternatively, it may be applied to a recording-only head equipped with no reproducing head section.

The method of manufacturing the perpendicular magnetic recording head of the invention is not limited to a case where all the steps described in the foregoing embodiments are included. The method of manufacturing the perpendicular magnetic recording head of the invention may include one or more steps other than those described above.

It is possible to use any of a CPP type GMR element, a CIP type (current in the plane) GMR element, and a TMR (tunneling magnetoresistance) element having a tunnel junction film as a reproduction element of the invention.

In the foregoing embodiment, each of the lower coil 18 and the upper coil 41 has a spiral structure in which it is wound on the stacked surface (in the XY plane); however, the invention is not limited thereto. Alternatively, for example the perpendicular magnetic recording head of the invention may include a coil having a helical structure in which the coil is wound so as to surround the magnetic pole 32 extending in a direction (Y-axis direction) orthogonal to the ABS 11S. Furthermore, regardless of which of the spiral structure and the helical structure is selected, the number of turns (number of windings) of the coils is not limited to a specific number and may be selected as appropriate.

The correspondence relationships between the reference numerals and the constituent elements of the present embodiment are collectively illustrated as follows.
1 . . . housing, 2 . . . magnetic disk, 3 . . . head arm assembly (HAA), 4 . . . head gimbals assembly (HGA), 4A . . . slider, 4B . . . suspension, 5 . . . arm, 6 . . . driver, 7 . . . fixed shaft, 8 . . . bearing, 9 . . . spindle motor, 10 . . . thin film magnetic head, 11 . . . base, 11A . . . element forming surface, 11S . . . air bearing surface (ABS), 13 . . . insulating layer, 14 . . . reproducing head section, 16 . . . recording head section, 17 . . . protective layer, 18 . . . lower coil, 181 . . . forward part, 182 . . . backward part, 19 . . . lower back gap, 20 (20A to 20D) . . . insulating layer, 21 . . . lower shield layer, 22 . . . MR element, 23 . . . upper shield layer, 24, 25, 27 . . . insulating layer, 26 . . . intermediate shield layer, 28 . . . lower yoke, 29 . . . leading shield, 31, 34, 35 . . . insulating layer, 32 . . . magnetic pole, 33 . . . trailing shield, 36 . . . pillar, 37 . . . side shield, 41 . . . upper coil, 411 . . . forward part, 412 . . . backward part, 43 . . . upper yoke, 44 . . . upper back gap, 45S . . . forward end surface, 50 . . . water-soluble resin film, 51 . . . first resist film, 51P . . . first resist pattern, BG . . . back gap, LG . . . leading gap, SG . . . side gap, TG . . . trailing gap

1. A method of manufacturing a perpendicular magnetic recording head, comprising:
forming a water-soluble resin film on a base;
forming a first resist pattern having an opening on the water-soluble resin film;
selectively dissolving the water-soluble resin film exposed at a bottom of the opening with a developer to expose a part of a surface of the base;
forming a non-magnetic oxide film to cover the opening and the exposed part of the surface of the base;
forming a second resist pattern to fill the opening covered with the non-magnetic oxide film and then removing the first resist pattern and the non-magnetic oxide film;
forming a first side shield and a second side shield on the base to allow the first side shield and the second side shield to face each other with the second resist pattern therebetween; and
forming a magnetic pole between the first side shield and the second side shield after removal of the second resist pattern.

2. The method of manufacturing a perpendicular magnetic recording head according to claim 1, further comprising subjecting the exposed part of the surface of the base to ashing, after the exposure of the part of the surface of the base and before the formation of the non-magnetic oxide film.

3. The method of manufacturing a perpendicular magnetic recording head according to claim 1, wherein the forming of the first resist pattern comprises:
forming a first resist film on the water-soluble resin film;
performing a first exposure processing that selectively exposes a part of the first resist film; and
selectively dissolving the exposed part of the first resist film or another part other than the exposed part in the developer to form the opening in the first resist film.

4. The method of manufacturing a perpendicular magnetic recording head according to claim 3, wherein
the first resist pattern is made of a positive resist, and
the second resist pattern is made of a negative resist,
and wherein
the removing of the first resist pattern and the non-magnetic oxide film includes performing a second exposure processing that exposes entire surfaces of the first resist pattern and the second resist pattern, and dissolving the first resist pattern in the developer.

5. The method of manufacturing a perpendicular magnetic recording head according to claim 1, wherein
the non-magnetic oxide film is formed with an atomic layer deposition (ALD) method.

6. The method of manufacturing a perpendicular magnetic recording head according to claim 1, wherein
the non-magnetic oxide film is formed using aluminum oxide.

7. The method of manufacturing a perpendicular magnetic recording head according to claim 1, wherein
the forming of the magnetic pole includes forming an insulating layer to cover a recess between the first side shield and the second side shield, and then forming a magnetic material to fill the recess covered with the insulating layer.

8. The method of manufacturing a perpendicular magnetic recording head according to claim 1, wherein
the water-soluble resin film is formed using polymethylglutarimide (PMGI), polyacrylic acid, polyvinyl acetal, polyvinyl pyrrolidone, polyvinyl alcohol, polyethyleneimine, polyethylene oxide, styrene-maleic acid copolymer, a polyvinylamine resin, polyallylamine, an oxazoline group-containing water-soluble resin, a water-soluble melamine resin, a water-soluble urea resin, an alkyd resin, or a sulfonamide resin.
